(19) United States
(12) Patent Application Publication
(10) Pub. No.: US 2016/0372161 A1
(43) Pub. Date: Dec. 22, 2016

(54) DATA STORAGE DEVICE AND OPERATING METHOD THEREOF

(71) Applicant: SK hynix Inc., Gyeonggi-do (KR)

(72) Inventor: Chol Su CHAE, Gyeonggi-do (KR)

(21) Appl. No.: 14/950,957

(22) Filed: Nov. 24, 2015

(30) Foreign Application Priority Data
Jun. 22, 2015 (KR) 10-2015-0088601

(51) Int. Cl. G11C 7/00; H03M 13/09; G11C 29/50; G06F 11/10

(52) U.S. Cl. CPC G11C 7/00; G06F 11/1004; H03M 13/096; G11C 29/50004; G11C 2029/5004

(57) ABSTRACT

A data storage device includes a nonvolatile memory apparatus including a target region; and a controller suitable for performing a read voltage adjustment operation including setting a plurality of test read voltages based on a reference read voltage and an offset value, reading a plurality of codewords from the target region by using the plurality of test read voltages, respectively, calculating a plurality of parity check sums respectively corresponding to the plurality of codewords, and selecting a final read voltage based on the plurality of parity check sums.

### CROSS-REFERENCES TO RELATED APPLICATION

The present application claims priority under 35 U.S.C. §119(a) to Korean application number 10-2015-0088601, filed on Jun. 22, 2015, which is incorporated herein by reference in its entirety.

### BACKGROUND

1. Technical Field

Various embodiments generally relate to a data storage device and, more particularly, to a data storage device capable of performing a read voltage adjustment operation.

2. Related Art

A data storage device stores data provided from an external device in response to a write request from the external device. The data storage device also provides the external device with stored data in response to a read request from the external device. The external device as referred to here is an electronic device capable of processing data, and may include a computer, a digital camera, a cellular phone and the like. The data storage device may be embedded in the external device, or may be fabricated separately and then coupled to the external device.

The data storage device may be prepared in the form of a Personal Computer Memory Card International Association (PCMCIA) card, a Compact Flash (CF) card, a smart media card, a memory stick, various multimedia cards (MMC, eMMC, RS-MMC, and MMC-Micro), various secure digital cards (SD, Mini-SD, and Micro-SD), a Universal Flash Storage (UFS), a Solid State Drive (SSD) and the like.

The data storage device may include a nonvolatile memory apparatus to store data. Nonvolatile memory is able to retain stored data even without a constant source of power. Nonvolatile memory includes flash memory, such as NAND flash or NOR flash, Ferroelectrics Random Access Memory (FeRAM), Phase-Change Random Access Memory (PCRAM), Magnetoresistive Random Access Memory (MRAM), Resistive Random Access Memory (ReRAM), and the like.

### SUMMARY

In an embodiment, a data storage device may include: a nonvolatile memory apparatus including a target region; and a controller suitable for performing a read voltage adjustment operation including setting a plurality of test read voltages based on a reference read voltage and an offset value, reading a plurality of codewords from the target region by using the plurality of test read voltages, respectively, calculating a plurality of parity check sums respectively corresponding to the plurality of codewords, and selecting a final read voltage based on the plurality of parity check sums.

In an embodiment, a method for operating a data storage device may include: performing a read voltage adjustment operation including setting a plurality of test read voltages based on a reference read voltage and an offset value; reading a plurality of codewords from a target region of a nonvolatile memory apparatus by using the plurality of test read voltages, respectively; calculating a plurality of parity check sums respectively corresponding to the plurality of codewords; and selecting a final read voltage among the plurality of test read voltages based on the plurality of parity check sums.

### BRIEF DESCRIPTION OF THE DRAWINGS

FIG. 1 is a block diagram exemplarily illustrating a data storage device in accordance with an embodiment.

FIGS. 2A to 2C are diagrams exemplarily illustrating threshold voltage distributions formed by memory cells.

FIG. 3 is a diagram exemplarily illustrating a parity check sum calculation method of an ECC unit shown in FIG. 1.

FIG. 4 is a flow chart exemplarily illustrating a method for operating a data storage device shown in FIG. 1.

FIGS. 5 to 7 are flow charts exemplarily illustrating a read voltage adjustment operation.

FIGS. 8A to 8C are diagrams exemplarily illustrating a read voltage adjustment operation of a data storage device shown in FIG. 1.

### DETAILED DESCRIPTION

Hereinafter, a data storage device and an operating method thereof according to the present invention will be described with reference to the accompanying drawings through exemplary embodiments. The present invention may, however, be embodied in different forms and should not be construed as limited to the embodiments set forth herein. Rather, these embodiments are provided to describe the present invention in detail to the extent that a person skilled in the art to which the invention pertains can enforce the technical concepts of the present invention.

It is to be understood that embodiments of the present invention are not limited to the particulars shown in the drawings, that the drawings are not necessarily to scale, and, in some instances, proportions may have been exaggerated in order to more clearly depict certain features of the invention. While particular terminology is used, it is to be appreciated that the terminology is for describing particular embodiments only and is not intended to limit the scope of the present invention.

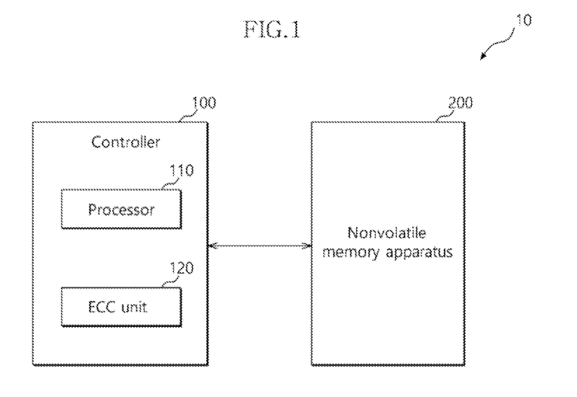

FIG. 1 is a block diagram exemplarily illustrating a data storage device 10 in accordance with an embodiment.

Referring to FIG. 1, the data storage device 10 may include a controller 100 and a nonvolatile memory apparatus 200.

The controller 100 may include a processor 110 and an error correction code (ECC) unit 120.

The processor 110 may control the general operations of the data storage device 10. The processor 110 may control the write operations of the nonvolatile memory apparatus 200 to store data in the nonvolatile memory apparatus 200 in response to a write request transmitted from an external device. The processor 110 may control the read operation of the nonvolatile memory apparatus 200 to read data stored in the nonvolatile memory apparatus 200 and output the read data to the external device in response to a read request transmitted from the external device.

The ECC unit 120 may encode data to be stored in the nonvolatile memory apparatus 200. The ECC unit 120 may encode data based on, for example, a low density parity check (LDPC) code, and generate encoded data, that is, a codeword.

The ECC unit 120 may decode the codeword read from the nonvolatile memory apparatus 200. In detail, the ECC unit 120 may first calculate a syndrome corresponding to the codeword based on a parity check matrix, and then, may determine whether the codeword includes an error, based on the calculated syndrome. When it is possible to correct the error included in the codeword, the ECC unit 120 may correct the error and output error-corrected data. When it is not possible to correct the error included in the codeword, the ECC unit 120 may determine the ECC decoding of the codeword to have failed. The ECC decoding may fail when the number of errors in the codeword are beyond the capability of the ECC unit 120 to correct.

According to the control of the controller 100, the nonvolatile memory apparatus 200 may perform a write operation for the data or the codeword transmitted from the controller 100, and may perform a read operation for the codeword stored therein and transmit read data to the controller 100. The nonvolatile memory apparatus 200 may include a plurality of memory cells (not shown) in which data are to be stored.

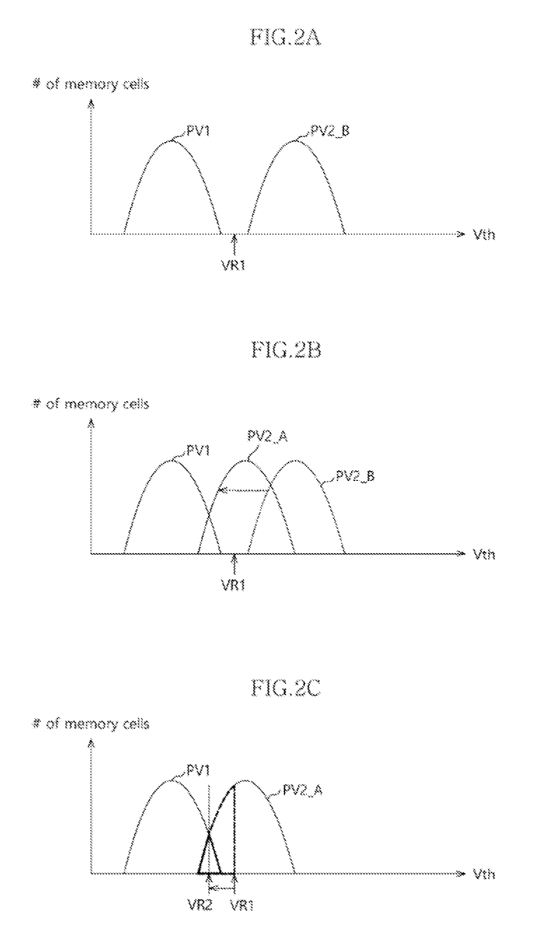

FIGS. 2A to 2C are diagrams exemplarily illustrating threshold voltage distributions PV1, PV2_B and PV2_A formed by memory cells. In the respective graphs of FIGS. 2A to 2C, the horizontal axis represents a threshold voltage, and the vertical axis represents the number of memory cells.

Referring to FIG. 2A, as respective memory cells have threshold voltages according to the data stored therein, the memory cells may form the threshold voltage distributions PV1 and PV2_B. For example, the memory cells stored with first data may form the threshold voltage distribution PV1, and the memory cells stored with second data may form the threshold voltage distribution PV2_B.

When a read operation is performed, the data stored in memory cells may be read from the memory cells as the threshold voltages of the memory cells are determined by a read voltage VR1. In detail, when the read voltage VR1 is applied to word lines corresponding to memory cells, the first data may be read from memory cells having threshold voltages less than the read voltage VR1, and the second data may be read from memory cells having threshold voltages greater than the read voltage VR1. The nonvolatile memory apparatus 200 may perform the write operation such that the interval or read margin between the threshold voltage distributions PV1 and PV2_B is sufficiently secured, and thus the threshold voltage distributions PV1 and PV2_B having the sufficiently secured read margin may be distinguished from each other by the read voltage VR1 during the read operation.

Referring to FIG. 2B, the threshold voltage distributions PV1 and PV2_B may have deformed shapes or move along the horizontal axis due to various reasons, for example, discharge of memory cells, interference or disturbance between adjacent memory cells, etc. The threshold voltage distribution PV2_B may move to be a threshold voltage distribution PV2_A. As a result, the threshold voltage distributions PV1 and PV2_A may partly overlap with each other, in which case read data may include errors during the read operation using the conventional read voltage VR1. The ECC decoding may fall when the number of errors included in the read data are beyond the capability of the ECC unit 120. The success probability of the ECC decoding may be inversely proportional to the number of errors included in the read data.

Referring to FIG. 2C, when the read voltage VR1 is adjusted to a read voltage VR2 with respect to the threshold voltage distributions PV1 and PV2_A, the errors included in read data may be minimized. In a region of dotted line shown in FIG. 2C, memory cells storing the second data may have a high probability of being read as storing the first data during the read operation using the conventional read voltage VR1. In other words, in the region of the dotted line, data read from the memory cells may have errors during the read operation using the conventional read voltage VR1. Even though data read from the memory cells in the solid line region shown in FIG. 2C may also have errors during the read operation using the adjusted read voltage VR2, the success probability of the ECC decoding may be greater with the adjusted read voltage VR2 than with the conventional read voltage VR1.

Namely, when the conventional threshold voltage VR1 corresponding to an optimal read point between the threshold voltage distributions PV1 and PV2_B is adjusted to the adjusted read voltage VR2 corresponding to another optimal read point between the threshold voltage distributions PV1 and PV2_A, the errors included in read data may be minimized. Because the success probability of the ECC decoding may be inversely proportional to the number of errors included in the read data, decoding of the read data may have a higher success probability with the adjusted read voltage VR2.

Referring again to FIG. 1, the controller 100 may perform a read voltage adjustment operation when it is determined to newly adjust the read voltage to correctly determine the threshold voltages of memory cells. When the ECC unit 120 fails in decoding the read data of a target region, the controller 100 may perform the read voltage adjustment operation for the decoding-failed target region. The decoding may fail when the data read from the target region includes errors exceeding the capability of the ECC unit 120 due to deformation of the threshold voltage distributions. The read voltage adjustment operation may be repeated as long as a repetition condition of the read voltage adjustment operation is satisfied.

A read voltage newly adjusted by the read voltage adjustment operation may be closer to an optimal read point between the threshold voltage distributions than the original read voltage. The controller 100 may adjust the read voltage through the read voltage adjustment operation in such a manner that the adjusted read voltage becomes closer to the optimal read point than the original read voltage. As will be described later, the read voltage adjustment operation may be repeatedly performed, and the read voltage newly adjusted each time the read voltage adjustment operation is repeatedly performed may become closer to the optimal read point than a previously adjusted read voltage, whereby a decoding success probability may be increased.

In detail, when the read voltage adjustment operation is performed, the processor 110 may set a plurality of test read voltages based on a reference read voltage and an offset value. An initial reference read voltage and an initial offset value may be preset according to the characteristics of the nonvolatile memory apparatus 200. The plurality of test read voltages may include, for example, first to third test read voltages. The second test read voltage may be the reference read voltage, and the first and third test read voltages may be lower and higher than the first test read voltage by the multiple amount of the offset value, respectively. However, it is to be noted that, in the embodiment, the number of test read voltages is not limited to 3.

The processor 110 may read first to third codewords from the target region by using the first to third test read voltages, respectively. In order to read the first to third codewords, the processor 110 may control the nonvolatile memory apparatus 200 in such a manner that the nonvolatile memory apparatus 200 performs first to third read operations for the target region by using the first to third test read voltages. The nonvolatile memory apparatus 200 performs the first to third read operations by applying the first to third test read voltages to a word line corresponding to the target region, and outputs the first to third codewords read from the target region, to the controller 100, under the control of the processor 110.

The ECC unit 120 may calculate first to third parity check sums respectively corresponding to the first to third codewords. Each of the first to third parity check sums may be the number of is included in each of first to third syndromes respectively calculated from the first to third codewords. For example, the first parity check sum may be the number of is included in the first syndrome calculated from the first codeword.

The processor 110 may select a final read voltage among the first to third test read voltages based on the first to third parity check sums. The processor 110 may select one among the first to third test read voltages corresponding to a minimum of the first to third parity check sums, as the final read voltage. A low parity check sum means a small number of errors included in the codeword. Therefore, a decoding success probability may be increased by selecting a test read voltage corresponding to the smallest parity check sum as a final read voltage.

According to an embodiment, in order to optimally select a final read voltage, the processor 110 may determine whether a condition for repeating the read voltage adjustment operation is satisfied. The controller 100 may repeatedly perform the read voltage adjustment operation according to a determination result. The processor 110 may increase a repetition count each time the read voltage adjustment operation is repeatedly performed. The processor 110 may reset the final read voltage as the reference read voltage of the next iteration during the repetition of the read voltage adjustment operation.

Moreover, the processor 110 may currently reset the offset value based on a previous offset value each time the read voltage adjustment operation is repeatedly performed. The currently reset offset value may be less than the previous offset value. The currently reset offset value may be half of the previous offset value. The currently reset offset value may be a maximum integer less than half of the previous offset value. When the previous offset value is 15, the currently reset offset value may be 7.

According to an embodiment, the processor 110 may determine whether the offset value is less than a threshold offset value. The controller 100 may repeatedly perform the read voltage adjustment operation until the offset value is less than a threshold offset value.

According to an embodiment, the processor 110 may determine whether the minimum among the first to third parity check sums is less than a threshold value. The controller 100 may repeatedly perform the read voltage adjustment operation until the minimum parity check sum is less than the threshold value. The threshold value may substantially ensure decoding success for the read codeword. The threshold value may be the parity check sum corresponding to a decoding-succeeded target region, which is different from the current target region.

According to an embodiment, the processor 110 may determine whether a repetition count has reached a threshold count. The controller 100 may repeatedly perform the read voltage adjustment operation until the repetition count has reached the threshold count.

The processor 110 may end the read voltage adjustment operation for the target region when the condition for repeating the read voltage adjustment operation is not satisfied. Thereafter, the processor 110 may instruct the ECC unit 120 to decode the read codeword corresponding to the final read voltage finally selected through the repetitive read voltage adjustment operations. The read codeword corresponding to the final read voltage may be read from the target region through a finally selected final read voltage during the repetitive read voltage adjustment operations. The ECC unit 120 may perform decoding of the read codeword corresponding to the finally selected final read voltage.

The processor 110 may set the finally selected final read voltage in the nonvolatile memory apparatus 200 when ending the read voltage adjustment operation. The processor 110 may transmit a setting command for setting the final read voltage to the nonvolatile memory apparatus 200. The nonvolatile memory apparatus 200 may store the final read voltage, and then may perform another read operation for the target region by using the stored final read voltage.

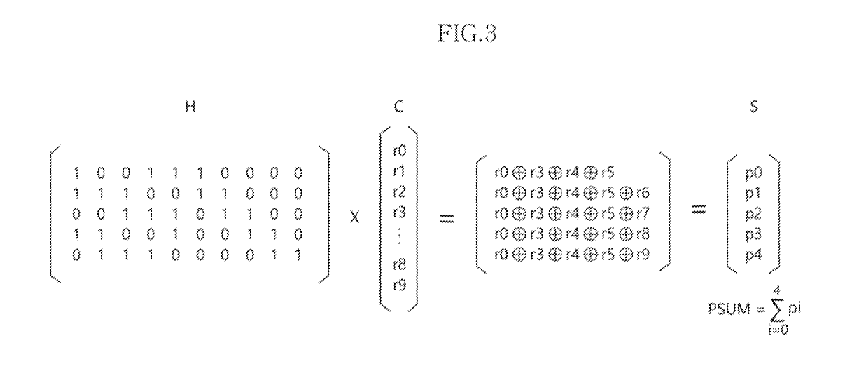

FIG. 3 is a diagram illustrating a parity check sum calculation method of the ECC unit 120 shown in FIG. 1. FIG. 3 exemplarily illustrates a parity check matrix H corresponding to the ECC unit 120.

Referring to FIG. 3, the ECC unit 120 may determine whether the read codeword includes an error based on the parity check matrix H.

The ECC unit 120 may perform multiplication of the parity check matrix H and a codeword matrix C constructed through the read codeword, and generate a syndrome S. For example, a parity check bit p0 constructing the syndrome S may be generated by the modulo-2 sum of bits r0, r3, r4 and r5 of the codeword.

The ECC unit 120 may calculate a parity check sum PSUM. The parity check sum PSUM may be the number of is included in the syndrome S. In other words, the parity check sum PSUM may be the sum of parity check bits p0 to p4 constructing the syndrome S. When the parity check sum PSUM is 0, the ECC unit 120 may determine that the codeword does not include an error, and, when the parity check sum PSUM is not 0, the ECC unit 120 may determine that the codeword includes an error.

As the parity check sum PSUM of the codeword is decreased, the probability of decoding the read codeword may increase since a decreased parity check sum means less errors in the read codeword. Namely, as the parity check sum PSUM of the read codeword decreases, the probability of decoding success for the read codeword may increase.

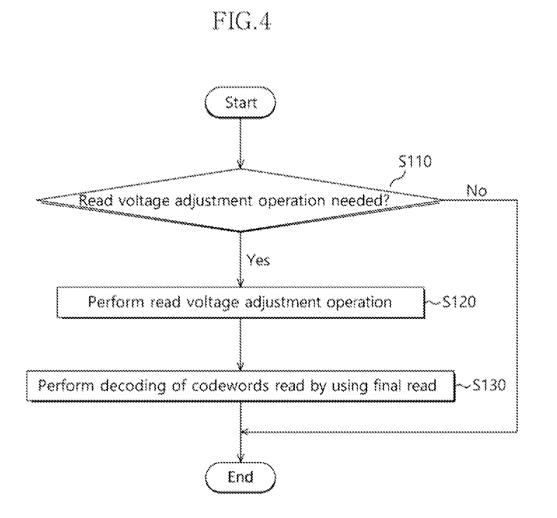

FIG. 4 is a flow chart exemplarily illustrating a method for operating the data storage device 10 shown in FIG. 1.

At step S110, the processor 110 may determine whether to perform the read voltage adjustment operation. When the ECC unit 120 fails in decoding the read data of a target region, the processor 110 may perform the read voltage adjustment operation for the decoding-failed target region (“Yes” of step S110). The decoding may fail when the data read from the target region includes the errors exceeding the capability of the ECC unit 120 due to deformation of the threshold voltage distributions.

At step S120, the controller 100 may perform the read voltage adjustment operation once or more for the target region. The final read voltage finally selected during the repetitive read voltage adjustment operation may increase the decoding success probability.

At step S130, the ECC unit 120 may perform decoding to the codeword read from the target region, by using the final read voltage selected in step S120.

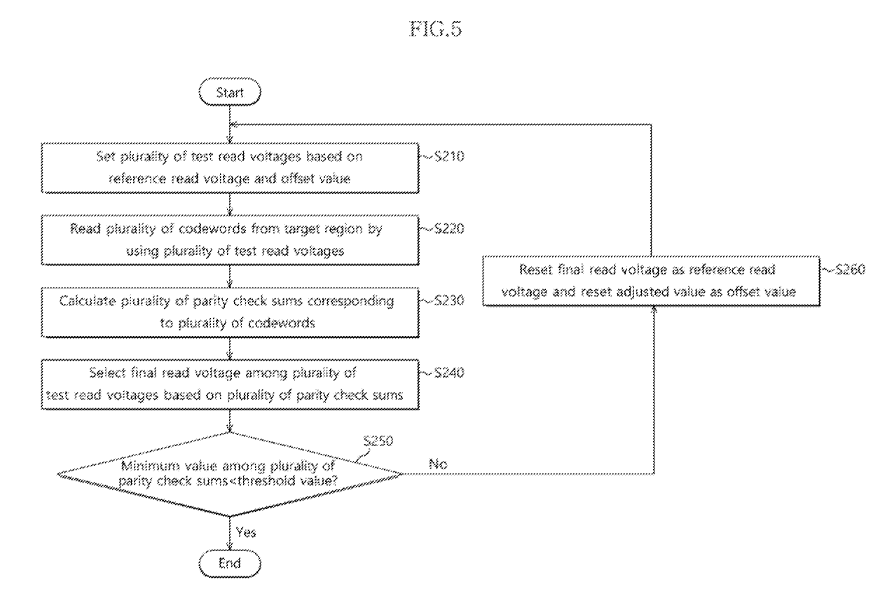

FIGS. 5 to 7 are flow charts exemplarily illustrating the read voltage adjustment operation. The processes illustrated in FIGS. 5 to 7 may correspond to step S120 described with reference to FIG. 4. The processes illustrated in FIGS. 5 to 7 may be substantially the same except for repetition conditions of the read voltage adjustment operation.

Referring to FIGS. 1 and 5, at step S210, the processor 110 may set the test read voltages based on the reference read voltage and the offset value. The test read voltages may include the reference read voltage, and other test read voltages higher and lower than the reference read voltage by a multiple amount of the offset value.

At step S220, the processor 110 may read a plurality of codewords from the target region by using the plurality of test read voltages. In order to read the plurality of codewords, the processor 110 may control the nonvolatile memory apparatus 200 in such a manner that the nonvolatile memory apparatus 200 performs a plurality of read operations for the target region by using the plurality of test read voltages.

At step S230, the ECC unit 120 may calculate the plurality of parity check sums respectively corresponding to the plurality of codewords. Each of the plurality of parity check sums may be the number of is included in each of the plurality of syndromes respectively calculated from the plurality of codewords, as described with reference to FIG. 1.

At step S240, the processor 110 may select the final read voltage among the plurality of test read voltages based on the plurality of parity check sums. The processor 110 may select one among the plurality of test read voltages corresponding to the minimum of the parity check sums, as the final read voltage. As described above, a low parity check sum means a small number of errors included in the codeword. Therefore, the decoding success probability may be increased by selecting the test read voltage corresponding to the lowest parity check sum as the final read voltage.

At step S250, the processor 110 may determine whether the minimum parity check sum is less than the threshold value. The threshold value may be the parity check sum corresponding to a decoding-succeeded target region, which is different from the current target region. When the minimum parity check sum is less than the threshold value (“Yes” of step S250), the process may end. When the minimum parity check sum is greater than or equal to the threshold value (“No” of step S250), the process may proceed to step S260.

At the step S260, the processor 110 may reset the final read voltage as the reference read voltage, and reset the offset value for the next iteration of the read voltage adjustment operation. The currently reset offset value may be half of the previous offset value and may be a maximum integer less than half of the previous offset value.

Thereafter, the processor 110 may repeat steps S210 to S260 based on the reset reference read voltage and the reset offset value until the minimum parity check sum is less than the threshold value.

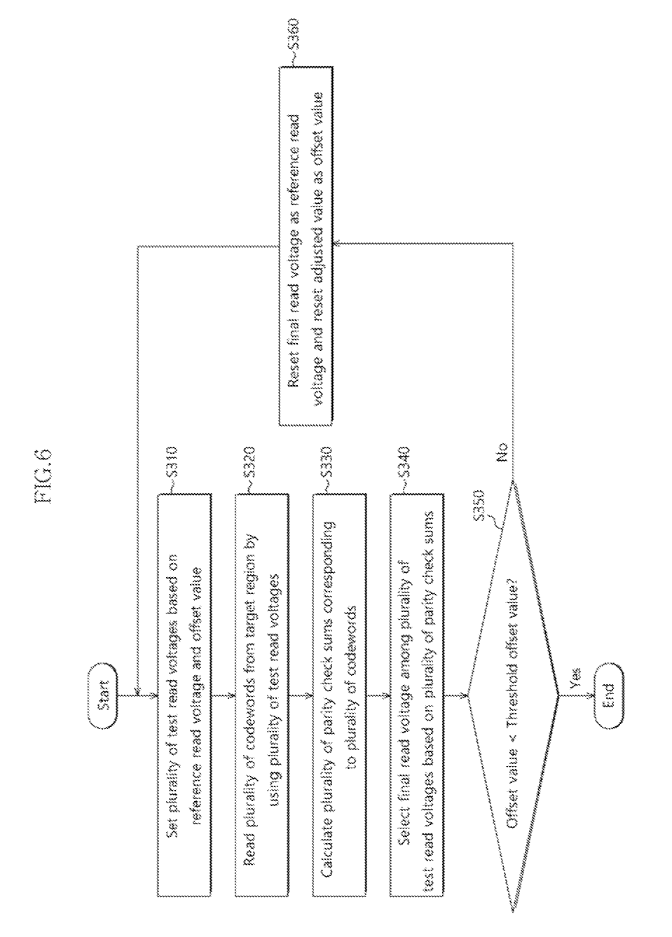

The operation method illustrated in FIG. 6 may be the same as the operation method described above with reference to FIG. 5 except for the repetition condition of the read voltage adjustment operation of step S350.

Referring to FIGS. 1 and 6, at step S350, the processor 110 may determine whether the offset value is less than the threshold offset value. When the offset value is less than the threshold offset value (“Yes” of step S350), the process may be ended. When the offset value is greater than or equal to the threshold offset value (“No” of step S350), the process may proceed to step S360, which correspond to step S260 described with reference to FIG. 5.

Thereafter, the processor 110 may repeat steps S310 to S360 based on the reset reference read voltage and the reset offset value until the offset value is less than the threshold offset value.

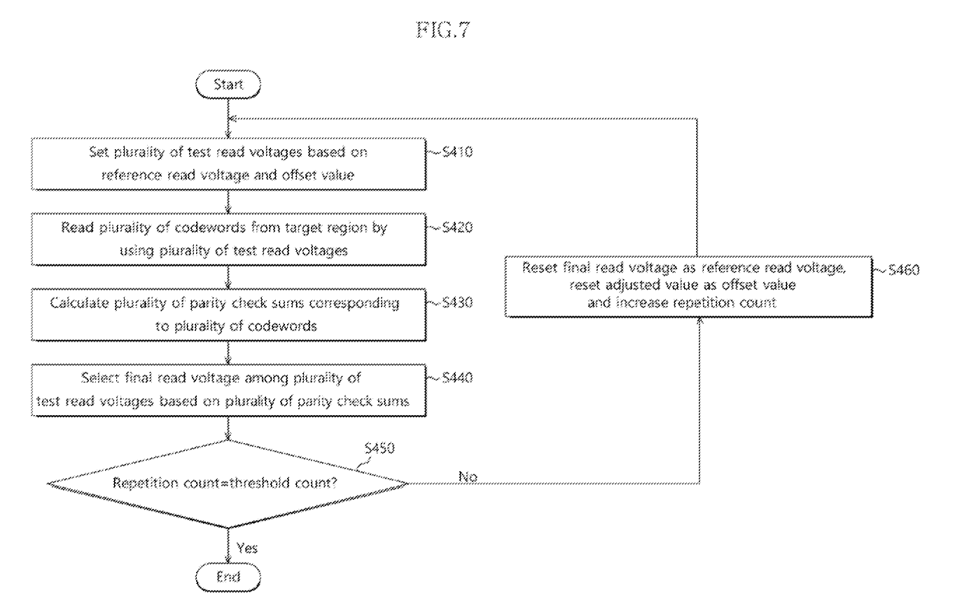

The operation method illustrated in FIG. 7 may be the same as the operation method described above with reference to FIG. 5 except for the repetition condition of the read voltage adjustment operation of step S450.

Referring to FIGS. 1 and 7, at step S450, the processor 110 may determine whether the repetition count has reached the threshold count. When the repetition count has reached the threshold count (“Yes” of step S450), the process may be ended. When the repetition count has not reached the threshold count (“No” of step S450), the process may proceed to step S460, which corresponds to step S260 described with reference to FIG. 5.

Thereafter, the processor 110 may repeat steps S210 to S260 based on the reset reference read voltage and the reset offset value until the repetition count has reached the threshold count.

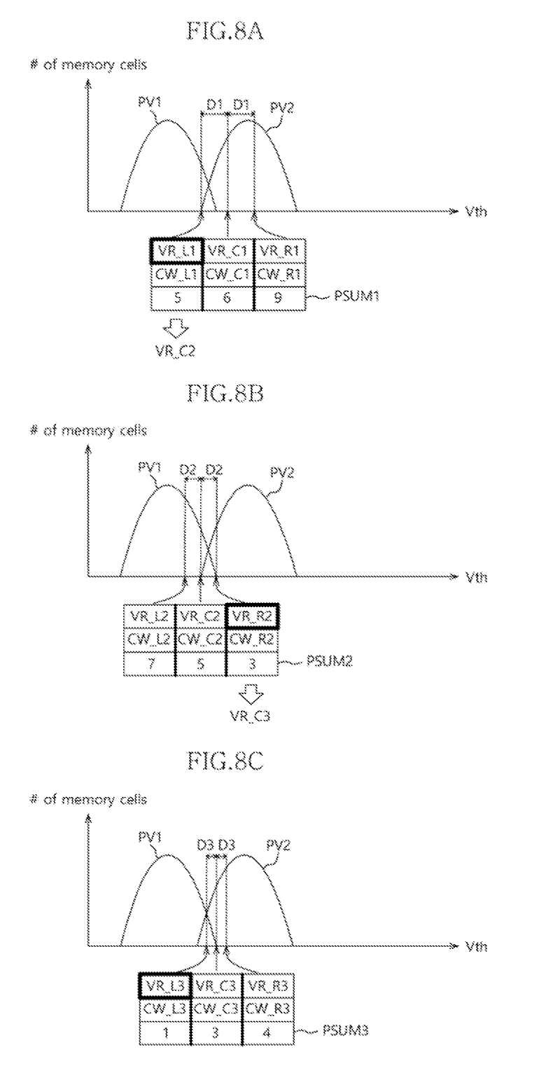

FIGS. 8A to 8C are diagrams exemplarily illustrating the read voltage adjustment operation of the data storage device 10 shown in FIG. 1. FIGS. 8A to 8C exemplarily illustrate overlapped threshold voltage distributions PV1 and PV2 formed by the memory cells of a target region.

Referring to FIGS. 1, 4 and 8A, the processor 110 may set the plurality of test read voltages, for example, first to third test read voltages VR_L1, VR_C1 and VR_R1, based on an initial reference read voltage VR_C1 and an initial offset value D1. The processor 110 may set the first test read voltage VR_L1 lower than the second test read voltage or the reference read voltage VR_C1 by the amount of the offset value D1, and set the third test read voltage VR_R1 higher than the second test read voltage or the reference read voltage VR_C1 by the amount of the offset value D1.

The processor 110 may read first to third codewords CW_L1, CW_C1 and CW_R1 from the target region by using the first to third test read voltages VR_L1, VR_C1 and VR_R1, respectively.

The ECC unit 120 may calculate first to third parity check sums PSUM1 respectively corresponding to the first to third codewords CW_L1, CW_C1 and CW_R1. Each of the first to third parity check sums PSUM1 may be the number of is included in each of first to third syndromes respectively calculated from the first to third codewords CW_L1, CW_C1 and CW_R1.

Among the first to third test read voltages VR_L1, VR_C1 and VR_R1, the processor 110 may select the first test read voltage VR_L1 corresponding to the minimum parity check sum “5” among the first to third parity check sums PSUM1 as the final read voltage.

The processor 110 may determine whether the repetition condition of the read voltage adjustment operation is satisfied. For example, the processor 110 may determine whether the minimum parity check sum “5” among the first to third parity check sums PSUM1 is less than the threshold value. The processor 110 may determine whether the offset value D1 is less than the threshold offset value and whether the repetition count has reached the threshold count.

According to the determination result of the repetition condition, the processor 110 may perform again the read voltage adjustment operation for the target region, and may reset the selected final read voltage VR_L1 as a new reference read voltage VR_C2. Further, the processor 110 may reset the offset value D1, for example, to half of the offset value D1 as a new offset value and the new reset offset value may be a maximum integer less than half of the offset value D1.

Referring to FIG. 8B, the processor 110 may perform again the read voltage adjustment operation for the target region. The processor 110 may set first to third test read voltages VR_L2, VR_C2 and VR_R2 based on the reset reference read voltage VR_C2 and a reset offset value D2. The processor 110 may set the first test read voltage VR_L2 lower than the second test read voltage or the reference read voltage VR_C2 by the amount of the offset value D2, and set the third test read voltage VR_R2 higher than the second test read voltage or the reference read voltage VR_C2 by the amount of the offset value D2.

The processor 110 may read first to third codewords CW_L2, CW_C2 and CW_R2 from the target region by using the first to third test read voltages VR_L2, VR_C2 and VR_R2, respectively.

The ECC unit 120 may calculate first to third parity check sums PSUM2 respectively corresponding to the first to third codewords CW_L2, CW_C2 and CW_R2.

Among the first to third test read voltages VR_L2, VR_C2 and VR_R2, the processor 110 may select the third test read voltage VR_R2 corresponding to the minimum parity check sum “3” among the first to third parity check sums PSUM2 as the final read voltage.

The processor 110 may determine whether the repetition condition of the read voltage adjustment operation is satisfied, and may perform again the read voltage adjustment operation for the target region according to the determination result. The processor 110 may reset the selected final read voltage VR_R2 as a new reference read voltage VR_C3, and may reset the offset value D2, for example, to half of the offset value D2 as a new offset value. The new reset offset value may be a maximum integer less than half of the offset value D2.

Referring to FIG. 8C, the processor 110 may perform again the read voltage adjustment operation for the target region. The processor 110 may set first to third test read voltages VR_L3, VR_C3 and VR_R3 based on the reset reference read voltage VR_C3 and a reset offset value D3. The processor 110 may set the first test read voltage VR_L3 lower than the second test read voltage or the reference read voltage VR_C3 by the amount of the offset value D3, and set the third test read voltage VR_R3 higher than the second test read voltage or the reference read voltage VR_C3 by the amount of the offset value D3.

The processor 110 may read first to third codewords CW_L3, CW_C3 and CW_R3 from the target region by using the first to third test read voltages VR_L3, VR_C3 and VR_R3, respectively.

The ECC unit 120 may calculate first to third parity check sums PSUM3 respectively corresponding to the first to third codewords CW_L3, CW_C3 and CW_R3.

Among the first to third test read voltages VR_L3, VR_C3 and VR_R3, the processor 110 may select the first test read voltage VR_L3 corresponding to the minimum parity check sum “1” among the first to third parity check sums PSUM3 as the final read voltage.

The processor 110 may determine whether the repetition condition of the read voltage adjustment operation is satisfied. For example, the processor 110 may determine whether the minimum parity check sum “1” among the first to third parity check sums PSUM3 is less than the threshold value, whether the offset value D3 is less than the threshold offset value, and whether the repetition count has reached the threshold count.

The controller 110 may end the read voltage adjustment operation according to the determination result. The processor 110 may instruct the ECC unit 120 to decode the codeword read from the target region by using the final read voltage VR_L3. The ECC unit 120 may perform decoding of the codeword read from the target region by using the final read voltage VR_L3, and may succeed in the decoding with a high probability.

While various embodiments have been described above, it will be understood to those skilled in the art that the embodiments described are examples only. Accordingly, the data storage device and the operating method thereof described herein should not be limited based on the described embodiments.

What is claimed is:

1. A data storage device comprising:
a nonvolatile memory apparatus including a target region; and
a controller suitable for performing a read voltage adjustment operation including:
setting a plurality of test read voltages based on a reference read voltage and an offset value,
reading a plurality of codewords from the target region by using the plurality of test read voltages, respectively,
calculating a plurality of parity check sums corresponding to the plurality of codewords, and
selecting a final read voltage based on the plurality of parity check sums.

2. The data storage device according to claim 1,
wherein the controller is further suitable for repeating the read voltage adjustment operation as long as a repetition condition is satisfied, and
wherein, at each repetition of the read voltage adjustment operation, the controller further resets the final read voltage as the reference read voltage, and resets the offset value for a next repetition of the read voltage adjustment operation.

3. The data storage device according to claim 2, wherein the controller repeats the read voltage adjustment operation until a minimum parity check sum at current repetition of the read voltage adjustment operation is less than a threshold value.

4. The data storage device according to claim 2, wherein the controller repeats the read voltage adjustment operation until a repetition count at current repetition of the read voltage adjustment operation has reached a threshold count.

5. The data storage device according to claim 2, wherein the controller repeats the read voltage adjustment operation until the offset value at a current repetition of the read voltage adjustment operation is less than a threshold offset value.

6. The data storage device according to claim 1, wherein the plurality of test read voltages include the reference read voltage, and two or more offset read voltages higher and lower than the reference read voltage by multiple amounts of the offset value.

7. The data storage device according to claim 1, wherein the plurality of parity check sums are numbers of is included in a plurality of syndromes calculated from the plurality of codewords, respectively.

8. The data storage device according to claim 1, wherein the controller selects one among the plurality of test read voltages corresponding to a minimum parity check sum as the final read voltage.

9. The data storage device according to claim 1, wherein the controller is further suitable for decoding one of the plurality of codewords read through the final read voltage.

10. The data storage device according to claim 1, wherein the controller performs the read voltage adjustment operation when decoding of data read from the target region falls.

11. A method for operating a data storage device comprising performing a read voltage adjustment operation including:
setting a plurality of test read voltages based on a reference read voltage and an offset value;
reading a plurality of codewords from a target region of a nonvolatile memory apparatus by using the plurality of test read voltages, respectively;
calculating a plurality of parity check sums corresponding to the plurality of codewords; and
selecting a final read voltage among the plurality of test read voltages based on the plurality of parity check sums.

12. The method according to claim 11,
further comprising repeating the read voltage adjustment operation as long as a repetition condition is satisfied,
wherein the read voltage adjustment operation further comprises resetting the final read voltage as the reference read voltage and resetting the offset value for a next repetition of the read voltage adjustment operation.

13. The method according to claim 12, wherein the repeating of the read voltage adjustment operation is performed until a minimum parity check sum at current repetition of the read voltage adjustment operation is less than a threshold value.

14. The method according to claim 12, wherein the repeating of the read voltage adjustment operation is performed until a repetition count at current repetition of the read voltage adjustment operation has reached a threshold count.

15. The method according to claim 12, wherein the repeating of the read voltage adjustment operation is performed until the offset value at current repetition of the read voltage adjustment operation is less than a threshold offset value.

16. The method according to claim 11, wherein the plurality of test read voltages include the reference read voltage, and two or more offset read voltages higher and lower than the reference read voltage by multiple amounts of the offset value.

17. The method according to claim 11, wherein the plurality of parity check sums are numbers of is included in a plurality of syndromes calculated from the plurality of codewords, respectively.

18. The method according to claim 11, wherein the selecting of the final read voltage selects one among the plurality of test read voltages corresponding to a minimum parity check sum as the final read voltage.

19. The method according to claim 11, further comprising decoding one of the plurality of codewords read through the final read voltage.
